(19) United States
(12) Patent Application Publication
(10) Pub. No.: US 2024/0309503 A1
(43) Pub. Date: Sep. 19, 2024

(54) ELECTRONIC DEVICE BASED ON MULTILAYER THIN FILM AND METHOD FOR MANUFACTURING THE SAME USING A THREE-DIMENSIONAL STRUCTURE

(71) Applicant: Woonkyung LEE, Seongnam-si (KR)

(72) Inventors: Woonkyung LEE, Seongnam-si (KR); Byung Hun LEE, Seongnam-si (KR)

(73) Assignee: Woonkyung LEE, Seongnam-si (KR)

(21) Appl. No.: 18/428,239

(22) Filed: Jan. 31, 2024

(30) Foreign Application Priority Data
Mar. 15, 2023 (KR) 10-2023-0033813

(51) Int. Cl. C23C 16/01; C23C 16/04; C23C 16/455; H01G 4/30; H01G 4/33; H01M 10/058

(52) U.S. Cl. CPC C23C 16/01; C23C 16/045; C23C 16/45536; C23C 16/45555; H01G 4/306; H01G 4/33; H01L 28/87; H01L 28/91; H01M 10/058; H01M 2300/0065

(57) ABSTRACT

An electronic device based on multilayer thin films includes: a thin film structure in the shape of a hollow microchannel plate, wherein the internal space of the microchannel plate, with multiple parallel microchannels arranged perpendicularly on the substrate's surface, is empty; and one or more layers of thin film pairs formed respectively on the inner and outer surfaces of the thin film structure.

### CROSS-REFERENCE TO PRIOR APPLICATION

This application claims priority to Korean Patent Application No. 10-2023-0033813 (filed on Mar. 15, 2023), which is hereby incorporated by reference in its entirety.

### BACKGROUND

The present disclosure relates to electronic device composed of densely integrated multilayer thin films, and a method for manufacturing the same using a three-dimensional structure with a high aspect ratio.

Electronic devices based on multilayer thin films, which are formed from multiple layers of thin films with similar or different characteristics, have been widely used in various fields such as displays, memory devices, piezoelectric devices, optical devices, and more. As the trend in downsizing various electronic equipment continues, the demand for high-density electronic components is increasing. Consequently, multilayer thin films that were traditionally arranged in planar configurations are now being arranged in the same space to occupy a larger surface area, thereby increasing integration.

A typical example of a device based on multilayer thin film is a capacitor. A capacitor is a device that stores capacitance as electrical potential energy in an electrical circuit by means of a dielectric film formed between two conductive thin films. One of the most challenging aspects of miniaturizing various electronic components is reducing the size of capacitors while ensuring sufficient capacitance. The capacitance C of a capacitor is calculated from the formula below.

$$C = {ε}_{r} . {ε}_{0} \frac{A}{d}$$

In the formula above, εᵣ represents the relative dielectric constant of the dielectric film, ε₀ represents the absolute dielectric constant of the dielectric film, A represents the area of the capacitor, and d represents the distance between the conductive thin films, which is the thickness of the dielectric film.

Research continues to enhance the performance of capacitors based on the formula above through three approaches: increasing the dielectric constant using high-k materials, increasing the area, and reducing the distance between the conductive thin films.

Among these approaches, a vertical structure has been developed to maximize the effective area of the capacitor within a given cell area. The structure of vertical capacitors is mainly divided into stacked structure and trench structure.

In stacked structures, capacitors need to be formed with a high height on the semiconductor substrate so that it has a large surface area in a small space to secure sufficient capacitance. However, there is a limit to increasing the capacitance by increasing the height of the stacked capacitor, as such a high height of the capacitor will make the etching process difficult during the subsequent bitline contact and storage node contact formation processes due to the step difference.

Trench capacitors form a trench inside the semiconductor substrate and use it as a capacitor, so unlike stacked capacitors, they can secure enough capacitance without the issues caused by the step difference. In order to increase the capacity of a trench capacitor, it is necessary to form a high aspect ratio trench to secure a large surface area in a small space, but if the trench is formed to have a depth of 50 or 100 μm or more, the following problems occur. Firstly, as the aspect ratio increases, it becomes difficult to etch with a uniform diameter, and a significant amount of processing time is required, leading to a sharp increase in processing costs. For example, etching a trench of 1.5 μm width to a depth of 30 μm requires at least 1 hour and 30 minutes per wafer. Additionally, high aspect ratio structures cause the substrate walls to collapse, twist, or stick together, or even form cracks due to stress applied to the substrate. Conventionally, there were problems with uneven deposition inside high aspect ratio trenches, leading to defects due to void formation. However, this issue has been addressed with the development of the ALD (atomic layer deposition) process, which enables uniform and reliable deposition even in narrow spaces. Moreover, thin film deposition using ALD can grow thin film, reducing the distance and thereby increasing the capacitance.

To alleviate the stress on substrates caused by high aspect ratio trenches, methods for patterning the arrangement of trenches have been proposed. U.S. Pat. No. 8,283,750 discloses the manufacture of high-density electronic device while maintaining the mechanical stability of the substrate using a tripod structure as shown in FIG. 1A. Korean Patent No. 10-2318995 proposes a method for forming g straight trenches as unit pattern that changes direction and extends according to an angle, as shown in FIG. 1B, to alleviate the stress on substrates caused by high aspect ratio trench structures.

However, these methods still require the formation of trenches in the substrate, and thus, the technical and cost-related problems associated with forming high aspect ratio trenches have not been resolved.

For the formation of high-density multilayer thin films, a cylindrical capacitor as shown in FIG. 1C has been proposed in prior arts. In cylindrical capacitors, a sacrificial film with multiple patterns is formed, and U-shaped charge storage electrodes are formed inside each of the multiple patterns. The sacrificial film is then removed, and multilayer thin films are formed on the inside and outside of the U-shaped electrodes. While cylindrical capacitors enable high-density integration, thereby enhancing the capacitance of the capacitors, they still involve etching processes and thus encompass the problems associated with creating high aspect ratio trench structures.

Additionally, a method for manufacturing capacitors using silicon nanowires as the substrate has been proposed. However, growing silicon nanowires is time-consuming, and due to the structural characteristics of the nanowires, they are prone to tilting or structural deformation, presenting an ongoing challenge that needs to be addressed.

### SUMMARY

An objective of the present disclosure is to provide a new structure of electronic device based on a vertical structure with high-density multilayer thin films.

To solve the problems of the related art for manufacturing electronic device based on multilayer thin films, which are based on a high aspect ratio trench, another objective of the present disclosure is to provide a method for manufacturing electronic device based on multilayer thin films without going through an etching process of a trench.

The technical challenge that the present disclosure intends to address may not be explicitly mentioned above, but it should be clearly understood by those with ordinary skill in the art.

To achieve the aforementioned objective, the present disclosure relates to electronic device with a new structure, which is based on a multilayer thin film and has a hollow microchannel plate-shaped thin film structure as a basic skeletal structure.

Specifically, one embodiment of the present disclosure's electronic device based on multilayer thin films is characterized by comprising a thin film structure in the shape of a hollow microchannel plate, wherein the internal space of the microchannel plate, with multiple parallel microchannels arranged perpendicularly on the substrate's surface, is empty; and one or more layers of thin film pairs formed respectively on the inner and outer surfaces of the thin film structure.

In another embodiment, the electronic device based on multilayer thin films is characterized by comprising a thin film structure in the shape of a hollow microchannel plate, wherein in addition to the internal space of the microchannel plate, with multiple parallel microchannels arranged perpendicularly on the substrate's surface, being empty, the bottom thin film is removed and the bottom ends of the microchannels are blocked; and one or more layers of thin film pairs formed respectively in the space created by a virtual thin film connecting the bottom ends of the microchannels and the inner surface of the thin film structure, and on the outer surface along the side of the microchannels. This embodiment of the electronic device may further include a carrier substrate combined to the bottom of the thin film structure.

The electronic device of the present disclosure, compared to conventional cylindrical electronic device with multilayer thin films formed on U-shaped structures, has an advantage of a larger effective surface area.

The electronic device of the present disclosure preferably has a center-to-center distance between adjacent microchannels of the thin film structure less than 5 μm, and an aspect ratio of the microchannels between 30 and 1000.

The electronic device of the present disclosure can have a conductive electrode layer, wherein the external areas of the outermost thin films of the inner and outer surfaces of the thin film structure are filled with conductive electrode materials. The conductive materials used for forming the conductive electrode layer can be precious metals, metals, heat-resistant metal nitrides, conductive oxides, or N+ doped polysilicon.

The multilayer thin films can be configured according to the purpose of the electronic device. For example, the device of the present disclosure can be a capacitor, in which case the multilayer thin films comprising the thin film structure and thin films formed on its inner and outer surfaces can be a structure wherein dielectric layers and conductive electrode layers are alternately stacked. Alternatively, the device of the present disclosure can be an all-solid-state battery, in which case the multilayer thin films comprising the thin film structure and thin films formed on its inner and outer surfaces can be a structure wherein conductive electrode layers and solid electrolyte layers are alternately stacked from the center.

Another aspect of the present disclosure is a method for manufacturing electronic device based on multilayer thin film, characterized by comprising steps of: (A) preparing a microchannel plate with multiple microchannels aligned perpendicularly to the surface; (B) depositing a thin film structure on the microchannel plate; (C) removing the microchannel plate; and (D) sequentially stacking one or more layers of thin film on both sides of the thin film structure.

One side of the microchannel plate may be attached to a carrier substrate, and in this case, an additional step of removing the carrier substrate can be included after step (D).

The microchannel plate used in step (A) is preferably made of glass or polymer material and ideally has an aspect ratio between 30 and 1000 for manufacturing high-density device. The thin film structure in step (B) and the multilayer thin films in step (D) can be deposited by ALD (atomic layer deposition) or PEALD (plasma enhanced atomic layer deposition). The thin film structure is preferably made of conductive electrode materials.

Step (C) involves removing the microchannel plate and manufacturing a three-dimensional thin film structure in the shape of a hollow microchannel plate. This step can be performed through wet etching, using a diluted solution of hydrofluoric acid or a mixture of NH₄F and HF. In this step, the microchannel plate can be completely removed or partially retained, for example, such that 0% to 10% of the thickness of the microchannel plate remains.

In step (D), the last thin film formed can be a conductive electrode layer. Alternatively, after stacking one or more layers of thin film, the remaining space, that is, the external areas of the outermost thin films of the inner and outer surfaces of the thin film structure, can be filled with conductive electrode materials to form an additional conductive electrode layer.

As described above, the electronic device based on multilayer thin films of the present disclosure has a larger surface area compared to conventional cylindrical electronic device, and is composed of high-density multilayer thin films, thus exhibiting superior characteristics.

Additionally, the electronic device based on multilayer thin films of the present disclosure is manufactured using a microchannel plate with high aspect ratio microchannels arranged perpendicularly and uniformly on the surface as a mold, which leads to high reliability, lower manufacturing costs, and easier capacity enhancement, thus economically providing device of superior quality.

### BRIEF DESCRIPTION OF THE DRAWINGS

FIGS. 1A and 1B are illustrative diagrams showing trench arrangements according to conventional technology.

FIG. 1C is a schematic diagram showing the structure of a cylindrical capacitor according to conventional technology.

FIG. 2 is a schematic diagram of a microchannel plate.

FIG. 3 shows transverse cross-sectional views and longitudinal cross-sectional views of the microchannel plate and the thin film structure.

FIG. 4 is an exemplary schematic diagram of the electronic device of the present disclosure.

FIG. 5 shows a diagram comparing the longitudinal cross-sections of electronic device of the present disclosure and conventional technology.

FIG. 6 shows the longitudinal cross-section of the thin film structure and electronic device of the second embodiment.

FIG. 7 is a diagram showing the manufacturing process of the electronic device of the present disclosure.

FIGS. 8A to 8G are schematic diagrams showing the manufacturing process of the electronic device of the present disclosure.

### BRIEF DESCRIPTION

The present disclosure is described in more detail below with reference to the accompanying drawings and examples. However, these drawings and examples are only illustrations for easily explaining the content and scope of the technical idea of the invention and do not limit or change the technical scope of the invention. It will be obvious to those skilled in the art that various modifications and changes can be made within the scope of the technical idea of the invention based on these examples. Furthermore, detailed descriptions of known technologies related to the invention will be omitted if they are deemed to unnecessarily obscure the essence of the invention.

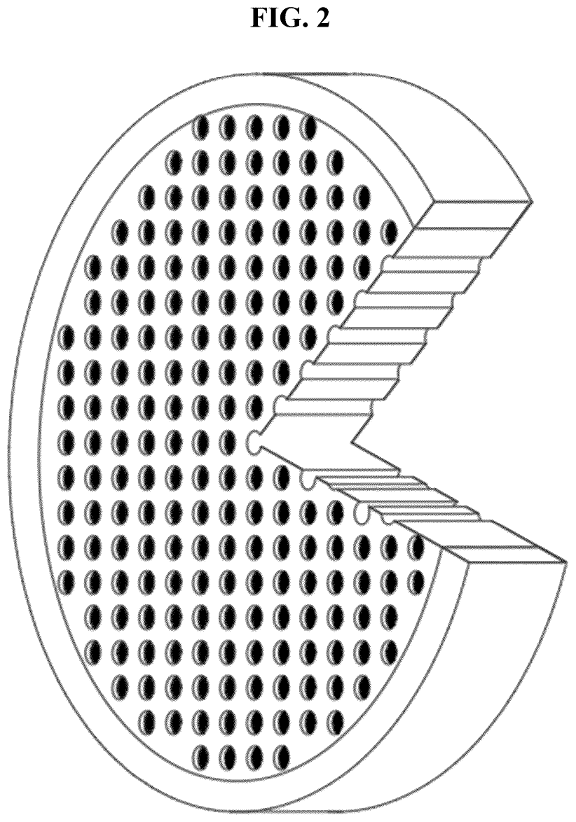

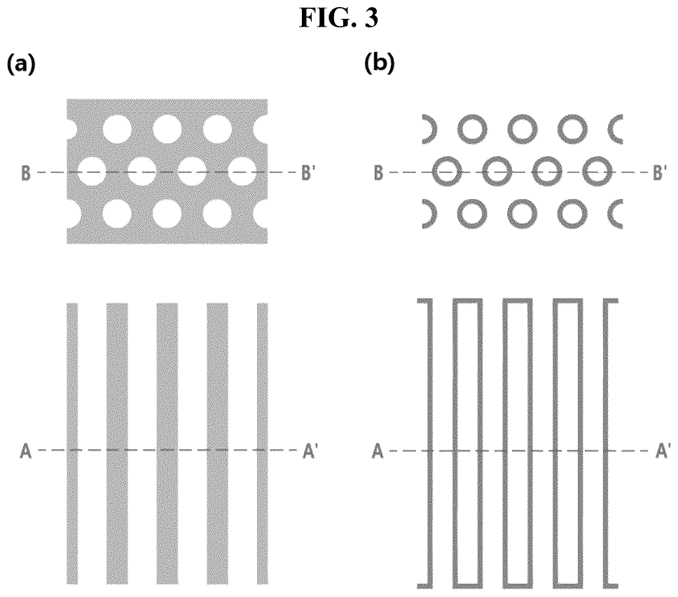

The present disclosure relates to electronic device with a new structure, which is based on a multilayer thin film and has a hollow microchannel plate-shaped thin film structure as a basic skeletal structure. FIG. 2 shows the general shape of a typical microchannel plate, while FIG. 3 includes schematic diagrams showing (a) the transverse cross-section (A-A′) and longitudinal cross-section (B-B′) of a microchannel plate, and (b) the transverse cross-section (A-A′) and longitudinal cross-section (B-B′) of the hollow microchannel plate shaped thin film structure of the present disclosure. In the drawings below, the thickness of the thin films and the spacing of the unit structure, and the like are arbitrarily scaled for convenience in explaining the present disclosure and do not reflect actual proportions. Therefore, the sizes of some components may be exaggerated compared to their actual size. As can be seen in FIG. 3, the thin film structure of the present disclosure has a hollow structure wherein the internal space of the substrate of the microchannel plate is empty, and the electronic device of the present disclosure is characterized by having this thin film structure as its basic skeletal structure.

Specifically, one embodiment of the present disclosure's electronic device based on multilayer thin films is characterized by comprising a thin film structure in the shape of a hollow microchannel plate, wherein the internal space of the microchannel plate, with multiple parallel microchannels arranged perpendicularly on the substrate's surface, is empty; and one or more layers of thin film pairs formed respectively on the inner and outer surfaces of the thin film structure. In the present disclosure, the outer surface refers to the exterior of the thin film structure, while the inner surface refers to the interior of the hollow structure. The concept of forming pairs on the inner and outer surfaces in the present disclosure means that the thin film materials formed on the inner and outer surfaces symmetrically form a set with respect to the thin film structure. That is, if three layers of thin films are formed on the inner surface of the thin film structure in the order of A-B-C from the thin film structure, then on the outer surface, thin films are also formed in the order of A′-B′-C′ from the thin film structure, resulting in the electronic device of the present disclosure having layers of C-B-A-thin film structure-A′-B′-C′ in repetition. In this case, paired does not mean that the thin films have the same overall shape or thickness, but the ratio between the paired layers can be the same, i.e., in the example above, the thickness ratio of layer B/A and the thickness ratio of layer B′/A′ can be the same.

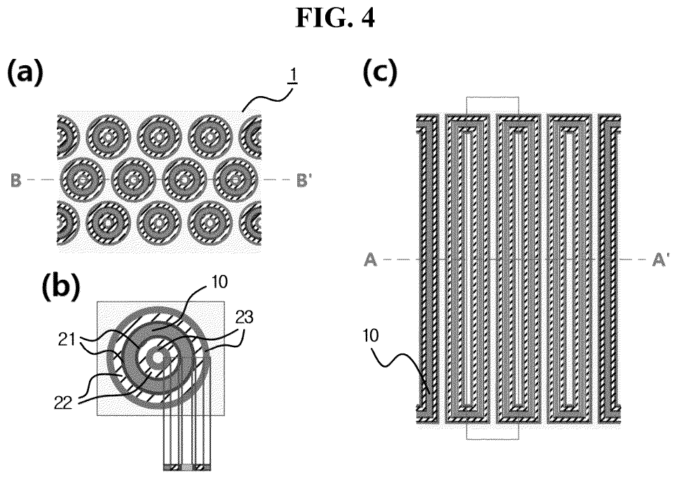

FIG. 4 is an exemplary schematic diagram of the electronic device of the present disclosure. While FIG. 4 illustrates that lines connecting the centers of adjacent microchannels in the same layer of the thin film structure (10) are arranged orthogonally to lines connecting the centers of adjacent microchannels in different layers above and below, other arrangements are of course not excluded. For convenience in explanation, the multilayer thin films formed within a single microchannel of a thin film structure are referred to as a single unit structure. In FIG. 4, (a) is a transverse cross-sectional view of the electronic device (1), (b) is a transverse cross-sectional view of a single unit structure, and (c) is a longitudinal cross-sectional view of the electronic device.

The electronic device of the present disclosure features unit structures with the following characteristics:

Firstly, the unit structure consists of a transverse cross-section passing through the central axis, comprising a multilayer thin film with 2n+1 layers (where n is an integer equal to or greater than 1) in concentric circles around the microchannel of the thin film structure. FIG. 4 shows an example of an electronic device with a unit structure where n=3. As previously mentioned, the multilayer thin films in this unit structure are illustrated at an arbitrary scale for example purposes only. In actual electronic devices, each layer can be independently selected to have an appropriate thickness that maximizes the function of each thin film layer and is suitable for enhancing the performance of the electronic device.

Secondly, the straight lines connecting the multilayer thin films in the above transverse cross-section are linearly symmetric with respect to the thin film structure, which is the n+1th layer positioned at the center of the multilayer thin films. As FIG. 4 illustrates a unit structure with n=3, the 4th layer is the thin film structure. FIG. 4, (b) demonstrates that the structure of the multilayer thin films is linearly symmetric with respect to the thin film structure. Linearly symmetric means that the materials of each layer form a symmetry. Additionally, the thickness ratio can also be linearly symmetric, and further, the thickness itself may be completely linearly symmetric.

Thirdly, it concerns the longitudinal cross-sectional shape. In one embodiment of the present disclosure, the longitudinal cross-section passing through the centers of the above unit structures forms] [-shaped structures of the thin film structure, as shown by the red rectangle in FIG. 4, (c), with paired thin films on the inside and outside of the thin film structure. Each of these thin films is interconnected with the corresponding thin film in the neighboring unit structure.

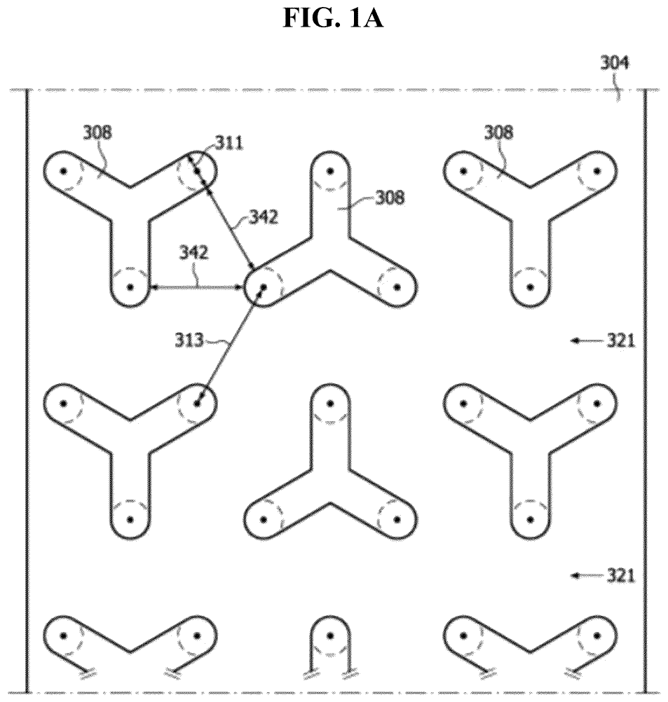

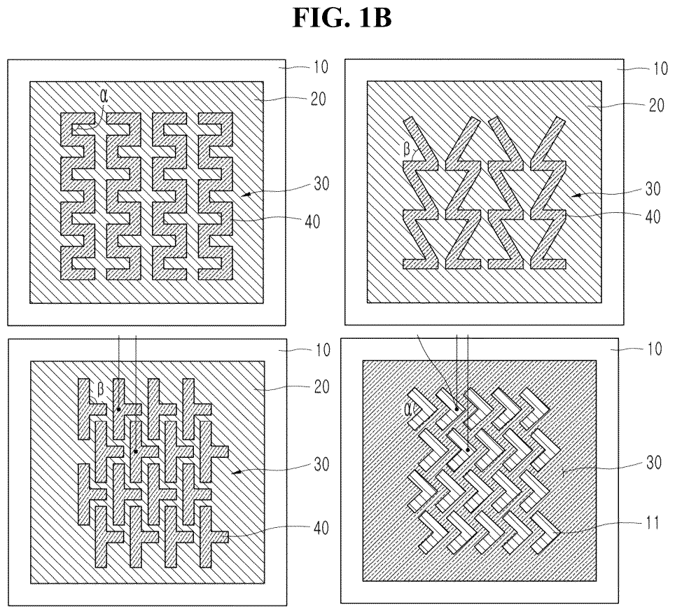

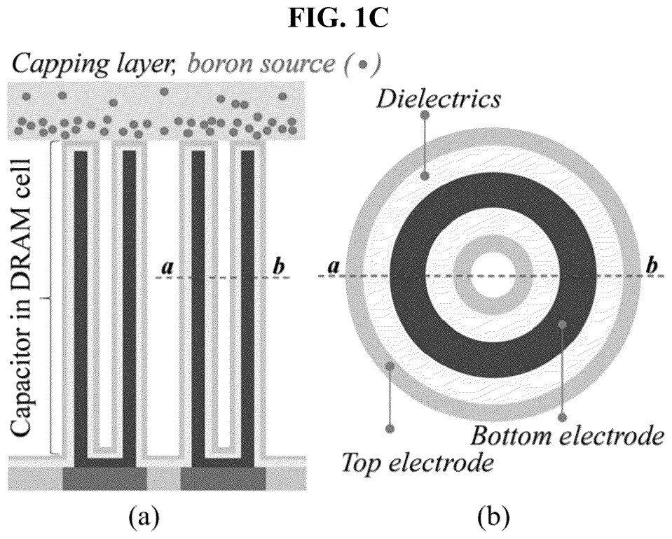

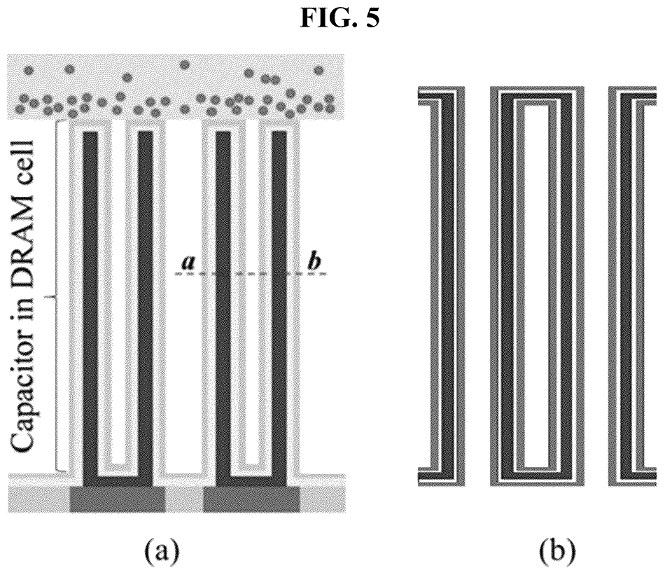

FIG. 5 compares the longitudinal cross-sectional views of (a) cylindrical electronic device using U-shaped structures according to conventional technology, and (b) electronic device of the present disclosure, which shares an identical transverse cross-sectional view. Both the conventional electronic device and the electronic device of the present disclosure are devices manufactured through film two thin stacking processes on structures (U-shaped and hollow microchannel plate, respectively) and have a transverse cross-sectional structure identical to that shown in FIG. 1C. In FIG. 5, comparing the longitudinal cross-sections, it can be seen that while only the sides and interior of the U-shaped electrodes in the conventional electronic device act as effective surface area, the electronic device of the present disclosure has multilayer thin films formed on both top and bottom of the electrode, acting as effective surface area in addition to the sides. As such, unlike the conventional electronic device where no thin films are stacked on the lower part of the U-shaped structure, the present disclosure has the effect of increasing the effective surface area where multilayer thin films are stacked, allowing for a higher density electronic device.

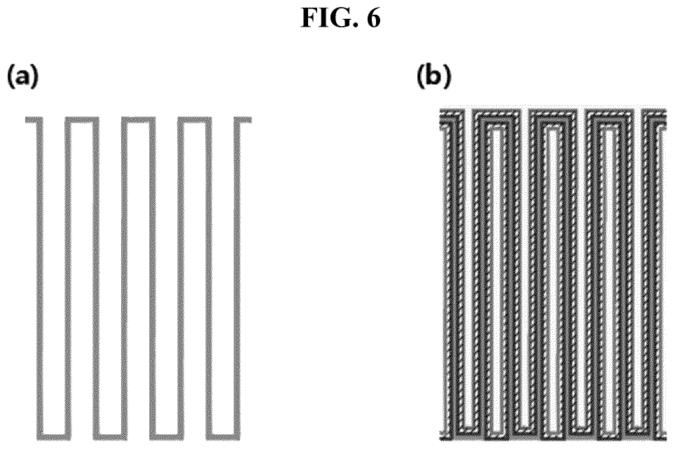

According to the second embodiment of the present disclosure, the electronic device based on multilayer thin films is characterized by comprising a thin film structure in the shape of a hollow microchannel plate, wherein in addition to the internal space of the microchannel plate, with multiple parallel microchannels arranged perpendicularly on the substrate's surface, being empty, the bottom thin film is removed and the bottom ends of the microchannels are blocked; and one or more layers of thin film pairs formed respectively in the space created by a virtual thin film connecting the bottom ends of the microchannels and the inner surface of the thin film structure, and on the outer surface along the side of the microchannels. FIG. 6 shows the longitudinal cross-sectional views (a) of the thin film structure and (b) of the electronic device according to the second embodiment of the present disclosure. The electronic device according to the second embodiment of the present disclosure differs from the first embodiment in the shape of the thin film structure and the location where the thin films are formed. In the electronic device according to the second embodiment, the thin film structure is characterized by the absence of the bottom thin film from the longitudinal cross-sectional view of the thin film structure according to the first embodiment, with the bottom ends of the microchannels being blocked instead. The terms “top” and “bottom” are arbitrarily designated for distinction in this description and do not refer to the concept of up and down during the use of the electronic device. Differences in the shape of the thin film structure leads to variations in the configuration of the thin films formed on it, resulting in a distinction where thin films are formed in the space created by a virtual thin film connecting the bottom ends of the microchannels and the inner surface of the thin film structure, and on the outer surface along the side of the microchannels. The term “virtual thin film” means that, although there is no actual thin film, it is assumed to be present. Assuming the presence of a thin film connecting the bottom ends of the microchannels, the thin film structure in this embodiment becomes a structure where one end of the microchannels in the hollow microchannel plate is blocked, and thin films are stacked onto its inner surface. Thus, while in the first embodiment, the thin films are formed on all outer surfaces of the thin film structure, in the second embodiment, no thin films are formed on the bottom side of the thin film structure. The electronic device of the second embodiment may additionally include a carrier substrate at the bottom of the thin film structure. The bottom of the thin film structure refers to the bottom side of a microchannel with a closed bottom end, i.e., the side without a thin film. Though carrier substrate is used to improve processability in the manufacturing process of the electronic device of the present disclosure, it may be retained for subsequent processes if needed. The material of the carrier substrate is not limited, as long as it does not affect the manufacturing process, and can include, for example, single-crystal silicon, polysilicon, hard glass, silicon oxide, but is not limited to these.

The electronic device of the present disclosure may additionally have a glass material support layer formed on the inner surface of the thin film structure. This support layer provides mechanical strength during the manufacturing process of the electronic device of the present disclosure, leading to a more regular alignment between unit structures.

The electronic device of the present disclosure features a structure with densely stacked multilayer thin films. It is preferable that the distance between the centers of adjacent microchannels in the thin film structure is less than 5 μm, and more preferably, 2 μm or less. The aspect ratio of these microchannels can be between 30 and 1000. As will be detailed in the manufacturing method described later, the electronic device of the present disclosure, unlike conventional electronic device, does not undergo a trench etching process. Thus, it is characterized by high aspect ratio cylindrical unit structures that are parallelly aligned without twisting. Therefore, it is possible to provide high-density electronic device with an aspect ratio of 30 or more, but it is also applicable to structures with lower aspect ratios.

In the present disclosure, it is preferable that the external areas of the outermost thin films of the inner and outer surfaces of the thin film structure, are filled with conductive electrode materials to form conductive electrode layers. Obviously, it does not exclude the possibility that the external areas of the outermost thin films of the inner and outer surfaces of the thin film structure could be layers other than conductive electrode layers, such as insulating layers. However, for ease of wiring for electrical connections and to maximize device density, it is beneficial to compose these layers as conductive electrode layers. The conductive materials used for forming the conductive electrode layer, for example, can be precious metals, metals, heat and oxidation-resistant metal nitrides, conductive oxides, or N+ doped polysilicon. For instance, the precious metals can be ruthenium (Ru), platinum (Pt), gold (Au), or iridium (Ir); the metal can be copper; the heat and oxidation-resistant metal nitrides can be titanium nitride (TiN), tantalum nitride (TaN), molybdenum nitride (MoN), or tungsten nitride (WN); and the conductive oxides can be ruthenium oxide (RuO₂), iridium oxide (IrO₂), or strontium ruthenium oxide (SrRuO₃).

In the electronic device of the present disclosure, the multilayer thin films formed by the thin film structure and thin films formed on its inner and outer surfaces can be designed depending on its specific implementations. For example, the device of the present disclosure can be a capacitor, in which case the multilayer thin films formed by the thin film structure and thin films formed on its inner and outer surfaces can be a structure where dielectric layers and conductive electrode layers are alternately stacked. The alternate stacking of conductive electrode layers and dielectric layers does not necessarily mean that each layer of conductive electrode and dielectric is stacked one layer at a time. To improve the performance of the device or to achieve the desired effect, for instance, one layer of conductive electrode layer and two dielectric layers composed of the first dielectric layer and the second dielectric layer can be repeatedly stacked. In this case, the dielectric layer is composed of the first and second dielectric layers, while overall, the structure has an alternating stacking of conductive electrode layers and dielectric layers. Furthermore, the present disclosure is characterized by the new structure of the electronic device and is not limited to specific materials constituting the conductive electrode layers and dielectric layers. Therefore, if the unit structure is formed by multilayer thin films with alternately stacked conductive electrode layers and dielectric layers, regardless of the specific materials, it falls within the scope of the present disclosure. The materials for the conductive electrode layers can include the materials previously mentioned, and the dielectric can be an oxide of one or more metals selected from silicon, zirconium, titanium, tantalum, hafnium, aluminum, alkali metals, and alkaline earth metals, or an ONO dielectric. Specifically, high dielectric materials such as BaTiO₃, PZT(Pb[ZrₓTi1−ₓ]O₃), Al₂O₃, TazO₃, HEO₂, ZrO₂, Ta₂O₅, BST((Ba,Sr)TiO₃), STO((Ba,Sr)TiO₃), HfSiOₓ, ZrSiOₓ, or ONO dielectrics can be used, but this is not limited to those, and low dielectric materials such as silicon oxide, alkali metal oxides, or alkaline earth metal oxides can also be used.

Another application of the electronic device of the present disclosure is an all-solid-state battery. A battery has a structure with electrolyte between the cathode and anode that allows ions to move between the two. All-solid-state batteries, which use a solid electrolyte, have the significant advantage of being safer than conventional liquid batteries due to the lack of side reactions caused by temperature changes or the risk of leakage due to external impacts. Additionally, since the solid electrolyte itself can function as a separator, there is no need for a separate separator, enabling the implementation of high-density batteries. However, the charge and ion conductivity of solid electrolytes are low, leading to very long charging and discharging times. To improve capacity and charging/discharging speed, it is necessary to increase the surface area and have a high-density structure with uniformly thin layers, repeatedly stacked, similar to a capacitor, in addition to improving the conductivity of the electrolyte. For this purpose, the present disclosure's electronic device can be configured as an all-solid-state battery, in which case the multilayer thin films formed by the thin film structure and thin films formed on its inner and outer surfaces can be a structure where conductive electrode layers and solid electrolyte layers are alternately stacked from the center. As explained in the case of capacitors, the present disclosure is not limited by the specific types of solid electrolytes used. The alternately stacked conductive electrode layers and solid electrolyte layers can each be composed of one or more layers. For example, the conductive electrode layer could consist of a base metal layer and a catalyst metal layer, stacked alternately as a set.

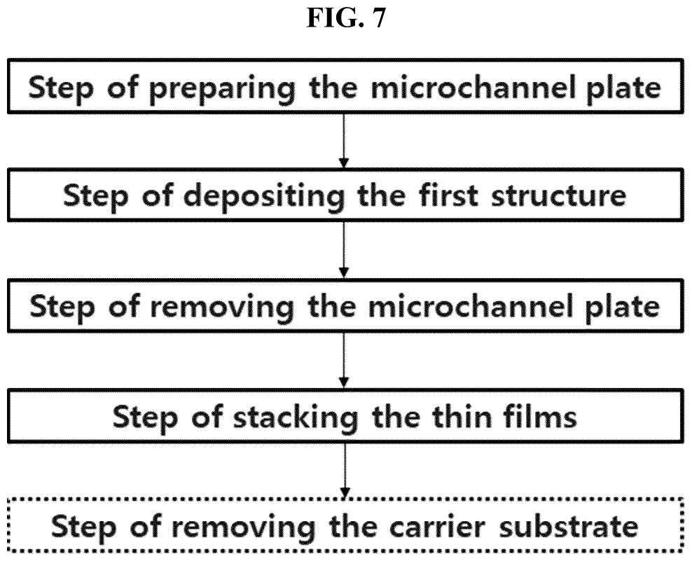

Another aspect of the present disclosure relates to a manufacturing method for the said electronic device based on multilayer thin films. The method for manufacturing the electronic device of the present disclosure is characterized by the use of a microchannel plate, which is a well-defined three-dimensional structure, as a mold. Specifically, the method of manufacturing of the present disclosure includes the steps of: (A) preparing a microchannel plate with multiple microchannels aligned perpendicularly to the surface; (B) depositing a thin film structure on the microchannel plate; (C) removing the microchannel plate; and (D) sequentially stacking one or more layers of thin film on both sides of the thin film structure; as shown in FIG. 7.

The microchannel plate used in step (A), as shown in FIG. 2, is a thin plate-like substrate with multiple through-holes, i.e., microchannels, of micro-unit diameter densely aligned at a perpendicular angle to the surface. Microchannel plates are utilized in various fields including optics, analytical devices, and filtration membranes. The microchannel plate can be made of glass or polymer material. Commercially available microchannel plates typically have a thickness of 0.5-1.5 mm, and the diameter of the hole ranges from 1 to several hundred Mm, with high aspect ratio microchannels densely and regularly arranged to have an open area ratio of at least 50%. Such commercial microchannel plates can be used in step (A). The inventors have filed a patent application for the method for manufacturing the microchannel plate on Mar. 9, 2023, under the application no. KR10-2023-0030990. According to the above application, a method for producing microchannel plates comprising steps of: (A) coating the surface of one or more strands of microfiber with a predetermined diameter with a polysilazane or polysiloxane binder; (B) winding one or more strands of binder-coated microfiber onto a bobbin to form microfiber bundle; (C) curing the binder while the shape of the microfiber bundle is fixed; and (D) slicing the binder-cured microfiber bundle to manufacture the plate; can minimize the conventional repetitive drawing-stacking process and provide a continuous automated process for manufacturing microchannel plates, thus economically providing high-quality microchannel plates through mass production.

The method for manufacturing the electronic device according to the present disclosure uses a microchannel plate with regularly and densely aligned high aspect ratio microchannels as a mold. Therefore, it does not require the etching process necessary for forming conventional trench structures, thus fundamentally solving the technical limitations associated with the formation of high aspect ratio trench structures and the problem of increased process costs during the formation of the trench structures.

The microchannel plate can be used with a carrier substrate attached to one side. The carrier substrate is attached to facilitate thickness adjustment and processing of the microchannel plate and can be used in its attached state to help with structural stability during the manufacturing process if it does not affect subsequent processes. The material of the carrier substrate can include, for example, single-crystal silicon, polysilicon, hard glass, or silicon oxide, but is not limited to these. Additionally, when using a microchannel plate with an attached carrier substrate, an additional step of removing the carrier substrate can be included after step (D).

For manufacturing high-density electronic device, it is preferable that the aspect ratio of the microchannels in the microchannel plate is between 30 and 1000. The aspect ratio of the microchannels in the thin film structure of the electronic device of the present disclosure is determined by the aspect ratio of the microchannels in the microchannel plate and the thickness of the thin film structure. Thus, an increase in the aspect ratio of the microchannels leads to an increase in the aspect ratio of the unit structure, enabling the manufacturing of high-density device. The diameter of the microchannels in the microchannel plate also influences the density of the electronic device. It is preferable for the diameter of the microchannels in the microchannel plate to be 5 μm or less, more preferably 2 μm or less, and even more preferably 1 μm. The open area ratio of the microchannel plate, determined by the diameter of the microchannels and their spacing, is preferably 50% or more, and more preferably 60% or more.

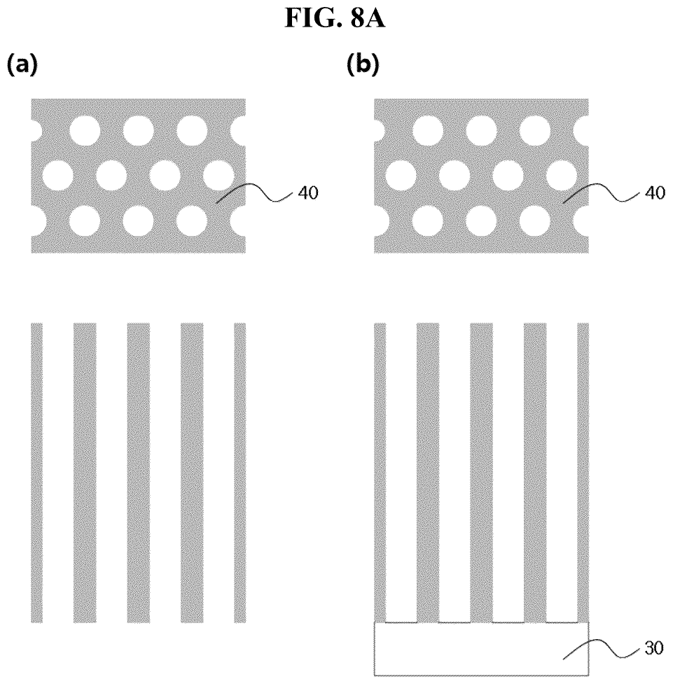

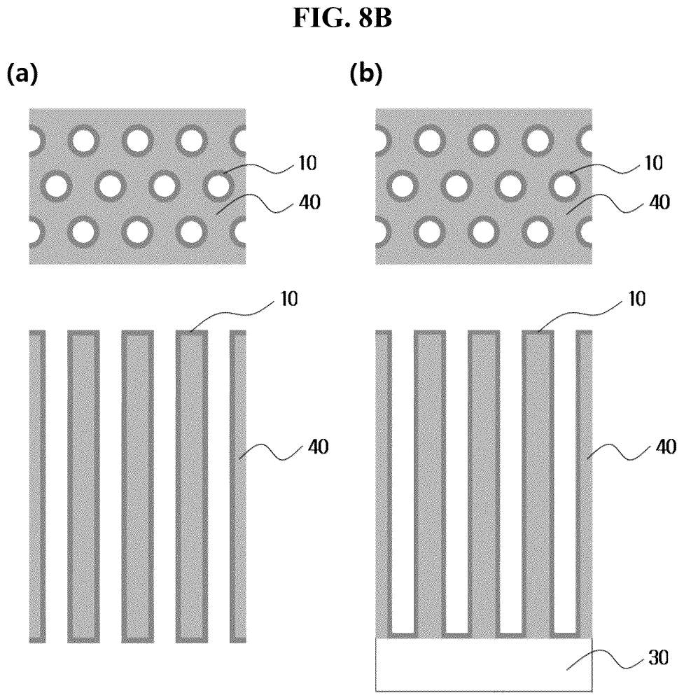

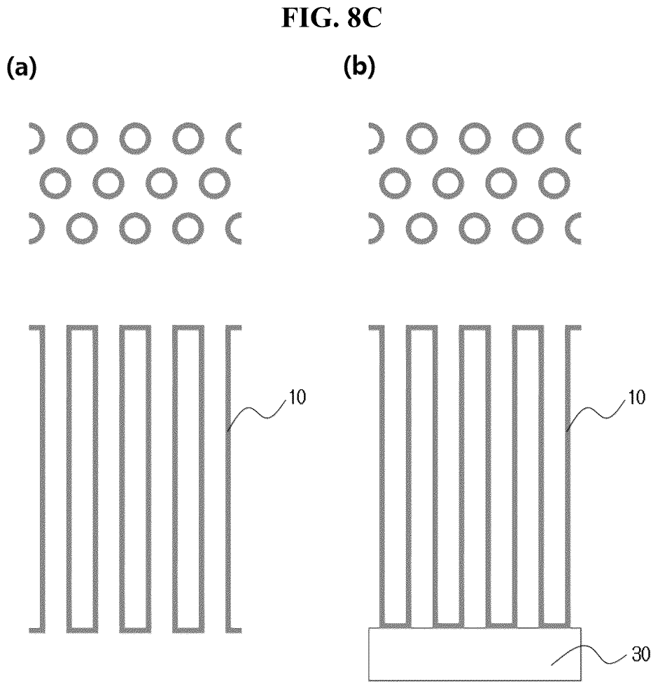

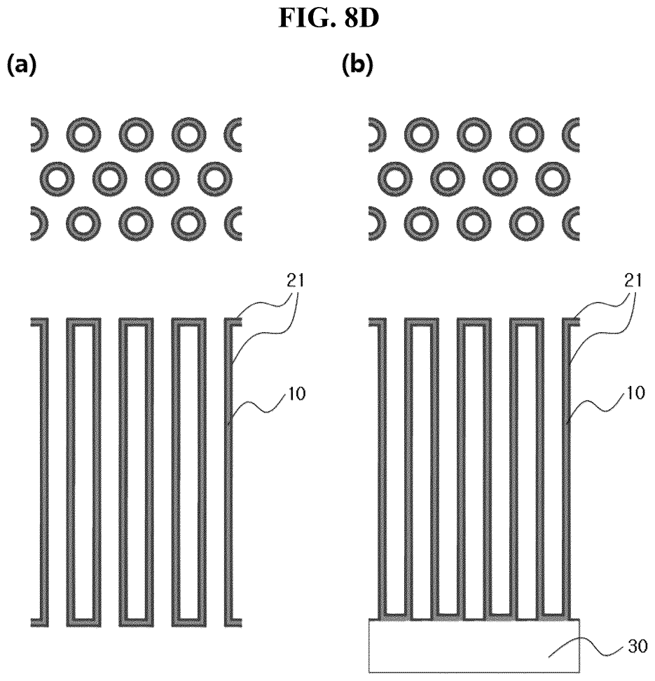

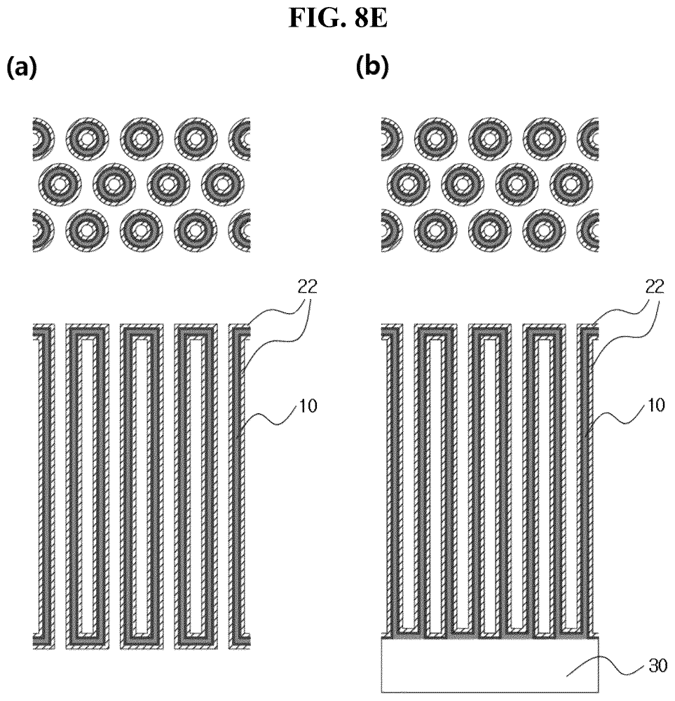

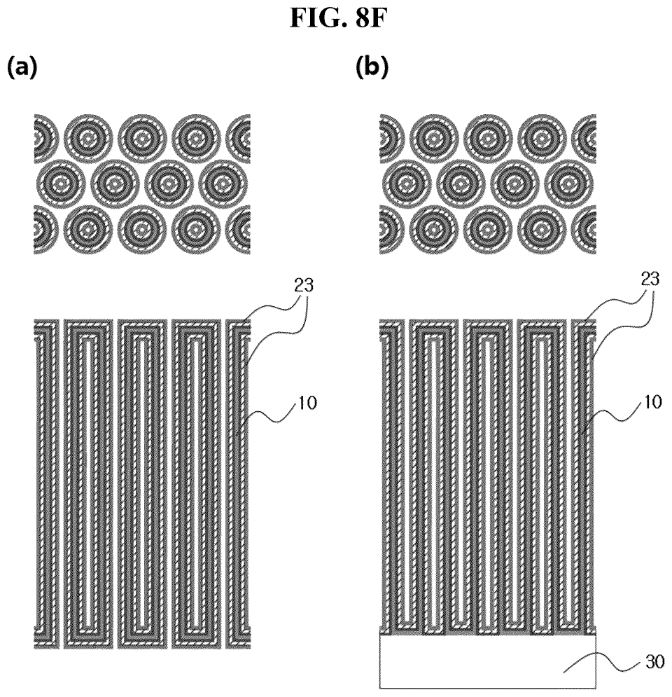

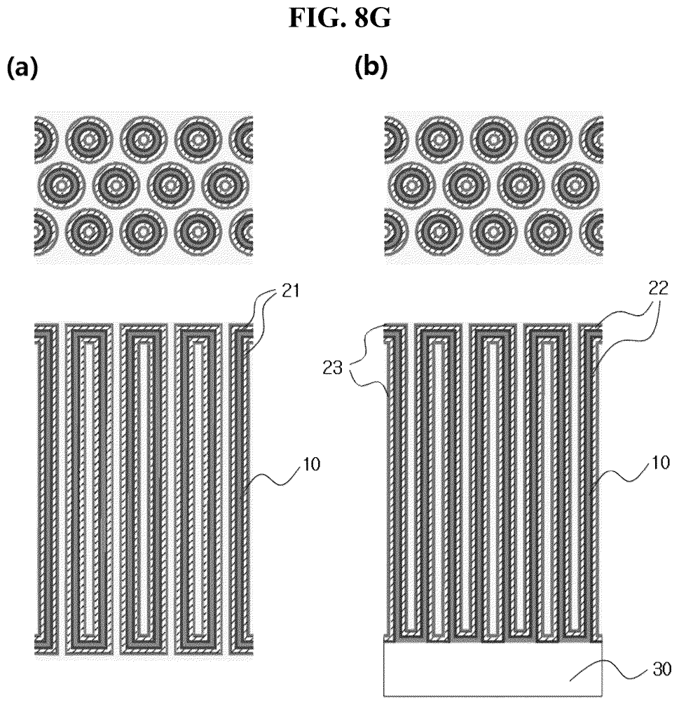

Step (B) involves depositing a thin film structure onto the prepared microchannel plate. FIG. 8A is a drawing showing the transverse (top) and longitudinal cross-section of the microchannel plate (40), and FIG. 8B is a drawing showing a thin film structure as deposited. The subsequent diagrams show (a) the manufacturing process of the electronic device using the microchannel plate itself, and (b) the process using the microchannel plate with an attached carrier substrate (30). As seen in FIG. 8B, the thin film structure is deposited on the microchannel plate in the form of a thin film. This step can be performed by a conventional CVD (chemical vapor deposition) process, but preferably by ALD (atomic layer deposition) or PEALD (plasma enhanced atomic layer deposition). Alternatively, it can be performed by methods like PCVD (pulsed CVD), SFD (sequential flow deposition), or MALD (modified ALD) which are partial applications of CVD and ALD. The thin film structure can be made of conductive electrode materials. Using conductive electrode materials for the thin film structure facilitates the selective removal of the microchannel plate in the subsequent step (C) and maintains structural stability even after the removal of the microchannel plate. Functional films like dielectric films are sensitive to thickness or damage during etching. However, conductive electrode layers are less sensitive to thickness or damage during etching, and are also easier to recover from such damages. The materials for the conductive electrode layer can be those described for the electronic device. Especially, conductive electrode materials like heat and oxidation-resistant metal nitrides as TiN are more such preferable.

Step (C) involves removing the microchannel plate to leave only the thin film structure. As shown in FIG. 8C, this step results in the formation of a thin film structure in the shape of a hollow microchannel plate or a hollow microchannel plate with one end of the microchannels blocked. In the thin film structure, the microchannels are aligned perpendicularly to the substrate surface, and parallel to each other. Since the microchannel plate is made of glass or polymer material, this step can be carried out using means that remove the microchannel plate without affecting the thin film structure. For example, if the microchannel plate is glass, it can be removed using a wet dip-out method with diluted hydrofluoric acid or a mixture of NH₄F and HF (BOE, buffered oxide etchant). This step can be performed as a full dip-out, completely removing the microchannel plate, or as a partial dip-out, leaving some of the microchannel plate. The residual microchannel plate can act as a support, reinforcing the thin film structure to prevent it from crushing or collapsing. However, too much residual microchannel plate can lower the density of the electronic device. Therefore, in the case of a partial dip-out, it is preferable to leave 10% or less of the thickness of the microchannel plate.

For carrying out this step (removing the microchannel plate after deposition), it is obvious that at least one opening, and preferably multiple openings within a range that does not impair the characteristics of the electronic device to be produced, must be formed in the thin film structure to expose the microchannel plate (not shown).

Step (D) involves forming one or more layers of thin film. After removing the microchannel plate in step (C), the thin film structure becomes a hollow microchannel plate structure, so thin films are formed both inside and outside the hollow microchannel plate simultaneously. Therefore, in this step, thin films are symmetrically stacked with reference to the thin film structure, as shown in FIG. 8D.

Though this step is simply described as stacking thin films, additional steps known in conventional technology can be included to speed up the stacking process or improve interfacial characteristics. For example, when stacking a dielectric film on a conductive electrode layer, an NH₃ plasma process be additionally performed on the conductive electrode layer to suppress deformation due to side reactions. Such additional processes are aimed at resolving issues accompanying the stacking of multilayer thin films and improving the characteristics of the formed thin films, and applying known techniques in conventional technologies should be easy for those skilled in the art. Additionally, although it has been mentioned that a microchannel plate with a carrier substrate attached to one side can be used in the present disclosure, depending on the circumstances, it is also possible to attach the carrier substrate after step (B) and in the middle of the stacking process in step (D), and this is not excluded.

In this embodiment, FIGS. 8D to 8F illustrate the formation of three layers of thin films on both the inner and outer surfaces of the thin film structure. Specifically, in this example, a multilayer thin film comprising the first pair of thin films (21), the second pair of thin films (22), and the third pair of thin films (23) is formed.

It is preferable that the last-formed thin film during the multilayer thin film formation is a conductive electrode layer. Alternatively, after step (D), it is preferable to include an additional step (E) to fill the external areas of the outermost thin films of the inner and outer surfaces of the thin film structure, with a conductive electrode material to form conductive electrode layers. FIG. 8G shows the process of filling the external areas of the outermost thin films of the inner and outer surfaces of the thin film structure after stacking the multilayer thin films. Alternatively, as thin films are simultaneously stacked inside and outside the thin film structure, and if the internal space is filled with the nth material's thin film while no thin film is formed in the external space, this step can be performed by filling the unfilled external space entirely with the nth material. The same applies in the opposite situation where the external space is filled and the internal space is not.

The specific components of the multilayer thin films in the method for manufacturing the electronic device of the present disclosure can be appropriately selected according to the purpose of the electronic device. For example, in the case of a capacitor, the multilayer thin films can be alternately composed of conductive metal layers and dielectric layers, and detailed explanations of this can be referred to in the description of the electronic device.

### DESCRIPTION OF REFERENCE NUMERAL

1: The electronic device
10: The thin film structure
21: The first pair of thin films 22: The second pair of thin films
23: The third pair of thin films
30: The carrier substrate
40: The microchannel plate

1. An electronic device based on multilayer thin films comprising:
a thin film structure in the shape of a hollow microchannel plate, wherein the internal space of the microchannel plate, with multiple parallel microchannels arranged perpendicularly on the substrate's surface, is empty; and
one or more layers of thin film pairs formed respectively on the inner and outer surfaces of the thin film structure.

2. The electronic device based on multilayer thin films of claim 1, wherein the thin film structure additionally includes a support layer made of glass material on its inner surface.

3. The electronic device based on multilayer thin films of claim 1, wherein the distance between the centers of adjacent microchannels in the thin film structure is less than 5 μm.

4. The electronic device based on multilayer thin films of claim 1, wherein the aspect ratio of the microchannels is between 30 and 1000.

5. The electronic device based on multilayer thin films of claim 1, wherein the external areas of the outermost thin films of the inner and outer surfaces of the thin film structure are filled with a conductive electrode material, forming conductive electrode layers.

6. The electronic device based on multilayer thin films of claim 5, wherein the materials used for forming the conductive electrode layers are precious metals, metals, heat-resistant metal nitrides, oxidation-resistant metal nitrides, conductive oxides, or N+ doped polysilicon.

7. The electronic device based on multilayer thin films of claim 5, wherein the electronic device is characterized as a capacitor, with the multilayer thin films formed by the thin film structure and thin films formed on its inner and outer surfaces can be a structure where dielectric layers and conductive electrode layers are alternately stacked.

8. The electronic device of claim 7, wherein the dielectric layer is composed of an oxide of one or more metals selected from silicon, zirconium, titanium, tantalum, hafnium, aluminum, alkali metals, and alkaline earth metals, or an ONO dielectric.

9. The electronic device based on multilayer thin films of claim 5, wherein the electronic device is characterized as an all-solid-state battery, with the multilayer thin films formed by the thin film structure and thin films formed on its inner and outer surfaces consisting of alternating layers of solid electrolyte and conductive electrode layers.

10. An electronic device based on multilayer thin films comprising:
a thin film structure in the shape of a hollow microchannel plate, wherein in addition to the internal space of the microchannel plate, with multiple parallel microchannels arranged perpendicularly on the substrate's surface, being empty, the bottom thin film is removed and the bottom ends of the microchannels are blocked; and
one or more layers of thin film pairs formed respectively in the space created by a virtual thin film connecting the bottom ends of the microchannels and the inner surface of the thin film structure, and on the outer surface along the side of the microchannels.

11. The electronic device based on multilayer thin films of claim 10, wherein the thin film structure additionally includes a support layer made of glass material on its inner surface.

12. The electronic device based on multilayer thin films of claim 10, wherein the distance between the centers of adjacent microchannels in the thin film structure is less than 5 μm.

13. The electronic device based on multilayer thin films of claim 10, wherein the aspect ratio of the microchannels is between 30 and 1000.

14. The electronic device based on multilayer thin films of claim 10, wherein the external areas of the outermost thin films of the inner and outer surfaces of the thin film structure are filled with a conductive electrode material, forming conductive electrode layers.

15. The electronic device based on multilayer thin films of claim 14, wherein the materials used for forming the conductive electrode layers are precious metals, metals, heat-resistant metal nitrides, oxidation-resistant metal nitrides, conductive oxides, or N+ doped polysilicon.

16. The electronic device based on multilayer thin films of claim 14, wherein the electronic device is characterized as a capacitor, with the multilayer thin films formed by the thin film structure and thin films formed on its inner and outer surfaces can be a structure where dielectric layers and conductive electrode layers are alternately stacked.

17. The electronic device of claim 16, wherein the dielectric layer is composed of an oxide of one or more metals selected from silicon, zirconium, titanium, tantalum, hafnium, aluminum, alkali metals, and alkaline earth metals, or an ONO dielectric.

18. The electronic device based on multilayer thin films of claim 14, wherein the electronic device is characterized as an all-solid-state battery, with the multilayer thin films formed by the thin film structure and thin films formed on its inner and outer surfaces consisting of alternating layers of solid electrolyte and conductive electrode layers.

19. The electronic device based on multilayer thin films of claim 10, wherein the bottom of the thin film structure includes an additional carrier substrate combined to it.

20. The electronic device based on multilayer thin films of claim 19, wherein the thin film structure additionally includes a support layer made of glass material on its inner surface.

21. The electronic device based on multilayer thin films of claim 19, wherein the distance between the centers of adjacent microchannels in the thin film structure is less than 5 μm.

22. The electronic device based on multilayer thin films of claim 19, wherein the aspect ratio of the microchannels is between 30 and 1000.

23. The electronic device based on multilayer thin films of claim 19, wherein the external areas of the outermost thin films of the inner and outer surfaces of the thin film structure are filled with a conductive electrode material, forming conductive electrode layers.

24. The electronic device based on multilayer thin films of claim 23, wherein the materials used for forming the conductive electrode layers are precious metals, metals, heat-resistant metal nitrides, oxidation-resistant metal nitrides, conductive oxides, or N+ doped polysilicon.

25. The electronic device based on multilayer thin films of claim 23, wherein the electronic device is characterized as a capacitor, with the multilayer thin films formed by the thin film structure and thin films formed on its inner and outer surfaces can be a structure where dielectric layers and conductive electrode layers are alternately stacked.

26. The electronic device of claim 25, wherein the dielectric layer is composed of an oxide of one or more metals selected from silicon, zirconium, titanium, tantalum, hafnium, aluminum, alkali metals, and alkaline earth metals, or an ONO dielectric.

27. The electronic device based on multilayer thin films of claim 23, wherein the electronic device is characterized as an all-solid-state battery, with the multilayer thin films formed by the thin film structure and thin films formed on its inner and outer surfaces consisting of layers alternating of solid electrolyte and conductive electrode layers.

28. A method for manufacturing the electronic device based on multilayer thin films, comprising steps of:
(A) preparing a microchannel plate with multiple microchannels aligned perpendicularly to the surface;
(B) depositing a thin film structure on the microchannel plate;
(C) removing the microchannel plate; and
(D) sequentially stacking one or more layers of thin film on both sides of the thin film structure.

29. A method for manufacturing the electronic device based on multilayer thin films of claim 28, wherein the microchannel plate is characterized as being made of glass or polymer material.

30. A method for manufacturing the electronic device based on multilayer thin films of claim 29, wherein the thin film structure is characterized as being composed of a conductive electrode material.

31. A method for manufacturing the electronic device based on multilayer thin films of claim 28, wherein the aspect ratio of the microchannels is characterized as being between 30 and 1000.

32. A method for manufacturing the electronic device based on multilayer thin films of any one of claim 28, wherein steps (A) and (C) are characterized as being performed by ALD or PEALD processes.

33. A method for manufacturing the electronic device based on multilayer thin films of claim 28, wherein step (B) is characterized as being carried out using diluted hydrofluoric acid or a mixture of NH₄F and HF.

34. A method for manufacturing the electronic device based on multilayer thin films of claim 28, wherein the method is characterized by retaining 0% to 10% of the thickness of the microchannel plate after step (B).

35. A method for manufacturing the electronic device based on multilayer thin films of claim 28, wherein the last thin film formed in step (D) is characterized as a conductive electrode layer.

36. A method for manufacturing the electronic device based on multilayer thin films of claim 28, wherein after step (D), the method additionally includes step of:
(E) filling the external areas of the outermost thin films of the inner and outer surfaces of the thin film structure with conductive electrode material to form a conductive electrode layer.

37. A method for manufacturing the electronic device based on multilayer thin films of claim 28, wherein the microchannel plate is characterized by having a carrier substrate attached to one of its surfaces.

38. A method for manufacturing the electronic device based on multilayer thin films of claim 37, wherein the microchannel plate is characterized as being made of glass or polymer material.

39. A method for manufacturing the electronic device based on multilayer thin films of claim 38, wherein the thin film structure is characterized as being composed of a conductive electrode material.

40. A method for manufacturing the electronic device based on multilayer thin films of claim 37, wherein the aspect ratio of the microchannels is characterized as being between 30 and 1000.

41. A method for manufacturing the electronic device based on multilayer thin films of any one of claim 37, wherein steps (A) and (C) are characterized as being performed by ALD or PEALD processes.

42. A method for manufacturing the electronic device based on multilayer thin films of claim 37, wherein step (B) is characterized as being carried out using diluted hydrofluoric acid or a mixture of NH₄F and HF.

43. A method for manufacturing the electronic device based on multilayer thin films of claim 37, wherein the method is characterized by retaining 0% to 10% of the thickness of the microchannel plate after step (B).

44. A method for manufacturing the electronic device based on multilayer thin films of claim 37, wherein the last thin film formed in step (D) is characterized as a conductive electrode layer.

45. A method for manufacturing the electronic device based on multilayer thin films of claim 37, wherein after step (D), the method additionally includes step of:
(E) filling the external areas of the outermost thin films of the inner and outer surfaces of the thin film structure with conductive electrode material to form a conductive electrode layer.

46. A method for manufacturing the electronic device based on multilayer thin films of claim 37, wherein the method further includes a step of removing the carrier substrate after step (D).

47. A method for manufacturing the electronic device based on multilayer thin films of claim 46, wherein the microchannel plate is characterized as being made of glass or polymer material.

48. A method for manufacturing the electronic device based on multilayer thin films of claim 47, wherein the thin film structure is characterized as being composed of a conductive electrode material.

49. A method for manufacturing the electronic device based on multilayer thin films of claim 46, wherein the aspect ratio of the microchannels is characterized as being between 30 and 1000.

50. A method for manufacturing the electronic device based on multilayer thin films of any one of claim 46, wherein steps (A) and (C) are characterized as being performed by ALD or PEALD processes.

51. A method for manufacturing the electronic device based on multilayer thin films of claim 46, wherein step (B) is characterized as being carried out using diluted hydrofluoric acid or a mixture of NH₄F and HF.

52. A method for manufacturing the electronic device based on multilayer thin films of claim 46, wherein the method is characterized by retaining 0% to 10% of the thickness of the microchannel plate after step (B).

53. A method for manufacturing the electronic device based on multilayer thin films of claim 46, wherein the last thin film formed in step (D) is characterized as a conductive electrode layer.

54. A method for manufacturing the electronic device based on multilayer thin films of claim 46, wherein after step (D), the method additionally includes step of:
(E) filling the external areas of the outermost thin films of the inner and outer surfaces of the thin film structure with conductive electrode material to form a conductive electrode layer.
